(19) United States
(12) Patent Application Publication
(10) Pub. No.: US 2007/0236590 A1
(43) Pub. Date: Oct. 11, 2007

(54) Output auto-zero for CMOS active pixel sensors

(75) Inventor: Brannon Harris, Austin, TX (US)

Correspondence Address: BLAKELY SOKOLOFF TAYLOR & ZAFMAN, 1279 OAKMEAD PARKWAY, SUNNYVALE, CA, 94085-4040, US

(73) Assignee: Cypress Semiconductor Corporation

(21) Appl. No.: 11/394,525

(22) Filed: Mar. 31, 2006

(51) Int. Cl. H04N 5/335; H01L 31/113

(52) U.S. Cl. 348/308

(57) ABSTRACT

Method and apparatus for dynamically biasing pixels in an image sensor array to remove pixel offset variations.

### TECHNICAL FIELD

The present invention relates generally to image sensors and, more particularly, to reducing common-mode voltage variation in CMOS active-pixel outputs.

### BACKGROUND

Solid-state image sensors are widely used in camera systems. The solid-state image sensors in some camera systems are composed of an array of rows and columns of picture elements (pixels) containing photosensitive elements. The photosensitive elements may be, for example, photodiodes, photogates, phototransistors or the like. When light is focused on the array, each photosensitive element converts a portion of the light it absorbs into electron-hole pairs and produces a charge that is proportional to the intensity of the light it receives. In some image sensor technologies, notably CMOS (complementary metal oxide semiconductor) fabrication processes, an array of pixels can be fabricated with integrated amplifying and switching devices in a single integrated circuit chip. A pixel with integrated electronics is known as an active pixel.

FIG. 1 illustrates a conventional four transistor (4T) active pixel 100. The 4T pixel includes a photodiode D₁, four MOSFET transistors including a transfer gate MTX, a reset gate MRX, a source follower MSF, a row select switch MRS, and a floating diffusion capacitance CFD at a sense node 102. The floating diffusion capacitance is the parasitic capacitance of the drain of MTX and the source of MRX. As noted above, D₁ is used to collect photocharge which is proportional to incident light. The reverse bias capacitance of the diode is also used to store the charge. The transfer gate MTX is used to isolate D₁ during exposure and to transfer the collected charge to the sense node 102 in the readout operations as described below. The reset gate MRX, is used to precharge the photodiode and the floating diffusion capacitance at the sense node 102. The source follower MSF is used to buffer the voltage at sense node 102. The row select switch MFS is used to connect the pixel to a column wire 101 shared by all the pixels in one column of the array. The pixels in a column of the array are typically biased with a high impedance current sink I₁ that provides current to the source follower MSF when the row select switch MFS connects the pixel to the column wire 101, allowing the pixel voltage to be impressed on output node 103.

FIG. 2 illustrates a 3×3 section 200 of a conventional sensor array of active pixels 100. A typical sensor array may have millions of pixels arranged in rows and columns. As illustrated in FIG. 2, each column is supplied with a bias current from a current sink ICOL, which is sequentially shared by each pixel in the column. As illustrated in FIG. 2, the control voltages VTRANSFER, VRESET and VSELECT may be common to all the pixels in a given row.

Ideally, when the pixel array is exposed to light, each photosensitive element collects photocharge, proportional to the light exposure in its vicinity, which is stored on the reversed bias capacitance of the diode. Then, the stored charged is transferred to the sense node and read out as a voltage on a row-by-row basis as pixels in each row are connected to their respective columns. However, real sensor arrays are not ideal.

One problem associated with conventional active pixel image sensors is that, due to process variations during fabrication, the pixel components (e.g., diodes, transistors) are not perfectly matched. Each pixel in an array exhibits a random variation in offset voltage at a given bias point. Typically, all of the pixels in an array are biased to the same current level (e.g., ICOL as illustrated in FIG. 2) for reasons of design simplicity. As a result, there is a random distribution of offset voltages across the array. These offset voltages add to the voltages generated by the photosensitive elements and distort the absolute amplitudes of the pixel outputs as well as the ratios of the pixel outputs. Without corrective measures, both the luminence (brightness) and the chrominance (color balance in the case of color image sensors) of the detected image can be distorted. The conventional approach to the offset problem is correlated double sampling.

In correlated double sampling, each pixel is read out twice, once when the pixel is reset (i.e., the charge from a previous exposure is removed) and again after the pixel is exposed. The offset is common to both readings and is eliminated by storing the first reading and then taking the difference between the first and second readings. With reference to FIG. 1, the 4T pixel 100 is typically operated by precharging sense node 102 using a voltage pulse on reset gate MRX with control voltage VRESET. When the pixel is connected to column wire 101 through row select transistor MRS by turning on MRS with control voltage VSELECT, the offset of the pixel can be sampled as an offset voltage at output node 103. For the purpose of this explanation, it is assumed that the photodiode D₁ is exposed to light and accumulates charge during or prior to the sense node precharge operation. The accumulated charge on D₁ is then transferred to the floating diffusion capacitance of sense node 102, by the operation of MTX, and appears as a voltage added to the offset voltage that can be sampled at output node 103. The offset voltage can then be eliminated by taking the difference between the two samples with differencing circuitry (not shown) that is known in the art.

This approach has several disadvantages that increase with the magnitude of the offset voltage: 1) the differencing circuit must have a high common mode rejection ratio, 2) the differencing circuit must have greater headroom, 3) the signal path losses for the reset and exposed modes must be matched, and 4) pixel gain non-uniformity is higher because of mismatch in source follower back bias.

### DESCRIPTION OF THE DRAWINGS

The present invention is illustrated by way of example, and not by limitation, in the figures of the accompanying drawings in which:

FIG. 1 illustrates a conventional four transistor active pixel;

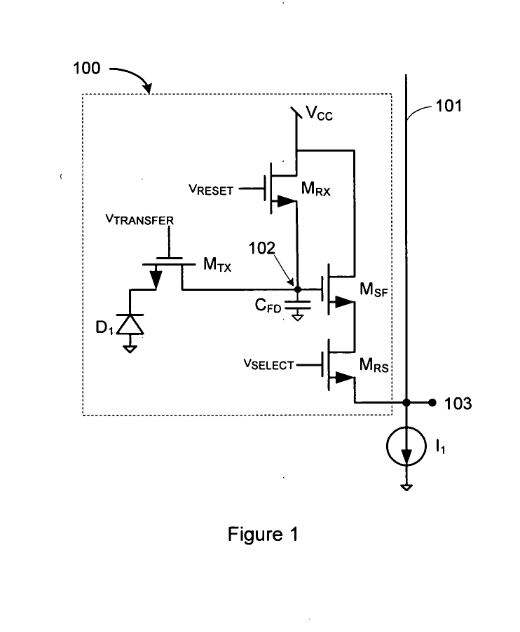

FIG. 2 illustrates a conventional active pixel array;

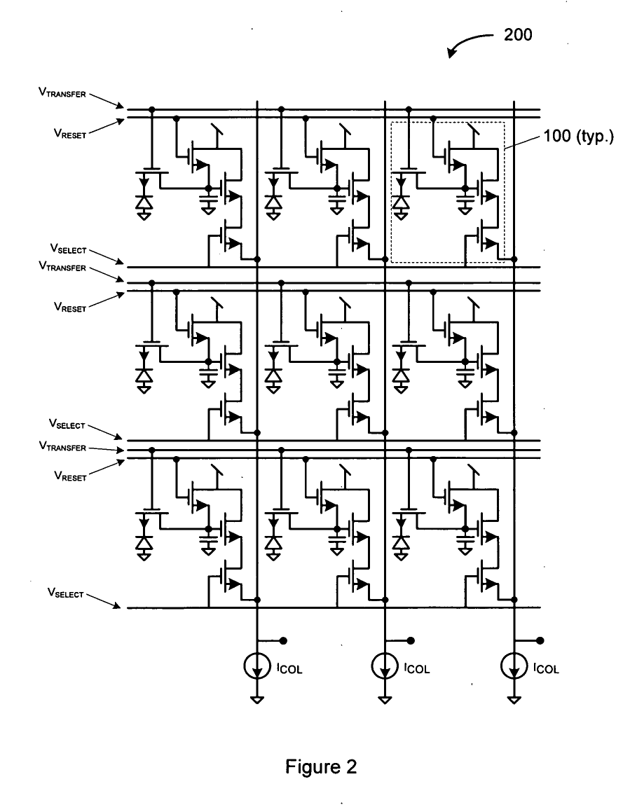

FIGS. 3A-3E illustrate output auto-zeroing in an active pixel in one embodiment;

FIG. 4 is a flowchart illustrating a method in one embodiment of output auto-zeroing in an active pixel;

FIG. 5 illustrates a system in which embodiments of the invention may be implemented.

### DETAILED DESCRIPTION

In the following description, for purposes of explanation, numerous specific details are set forth in order to provide a thorough understanding of the present invention. It will be evident, however, to one skilled in the art that the present invention may be practiced without these specific details. In other instances, well-known circuits, structures and techniques are not shown in detail or are shown in block diagram form in order to avoid unnecessarily obscuring an understanding of this description.

References throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention. In addition, while the invention has been described in terms of several embodiments, those skilled in the art will recognize that the invention is not limited to the embodiments described. The embodiments of the invention can be practiced with modification and alteration within the scope of the appended claims. The specification and the drawings are thus to be regarded as illustrative instead of limiting on the invention.

Embodiments of the present invention include circuits, to be described below, which perform operations. Alternatively, the operations of the present invention may be embodied in machine-executable instructions, which may be used to cause a general-purpose or special-purpose processor programmed with the instructions to perform the operations. Alternatively, the operations maybe performed by a combination of hardware and software.

Embodiments of the present invention may be provided as a computer program product, or software, that may include a machine-readable medium having stored thereon instructions, which may be used to program a computer system (or other electronic devices) to perform a process according to the present invention. A machine readable medium includes any mechanism for storing or transmitting information in a form (e.g., software, processing application) readable by a machine (e.g., a computer). The machine readable medium may include, but is not limited to: magnetic storage media (e.g., floppy diskette); optical storage media (e.g., CD-ROM); magneto-optical storage media; read only memory (ROM); random access memory (RAM); erasable programmable memory (e.g., EPROM and EEPROM); flash memory; electrical, optical, acoustical or other form of propagated signal; (e.g., carrier waves, infrared signals, digital signals, etc.); or other type of medium suitable for storing electronic instructions.

Some portions of the description that follow are presented in terms of algorithms and symbolic representations of operations on data bits that may be stored within a memory and operated on by a processor. These algorithmic descriptions and representations are the means used by those skilled in the art to effectively convey their work. An algorithm is generally conceived to be a self-consistent sequence of acts leading to a desired result. The acts are those requiring manipulation of quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, parameters or the like.

The term “coupled to” as used herein may mean coupled directly to or indirectly to through one or more intervening components. Any of the signals provided over various buses described herein may be time multiplexed with other signals and provided over one or more common buses. Additionally, the interconnection between circuit components or blocks may be shown as buses or as single signal lines. Each of the buses may alternatively be one or more single signal lines, and each of the single signal lines may alternatively be buses.

Methods and apparatus for output auto-zeroing of a CMOS active pixel are described. In one embodiment, a method includes dynamically biasing an active pixel with a bias current to obtain a reference offset voltage and maintaining the bias current while transferring charge from a photodiode in the active pixel to a sense node of the active pixel.

In one embodiment, an apparatus includes one or more active pixels in a column of active pixels, and a column amplifier coupled with the column of active pixels to drive an offset voltage of a selected active pixel to a reference voltage.

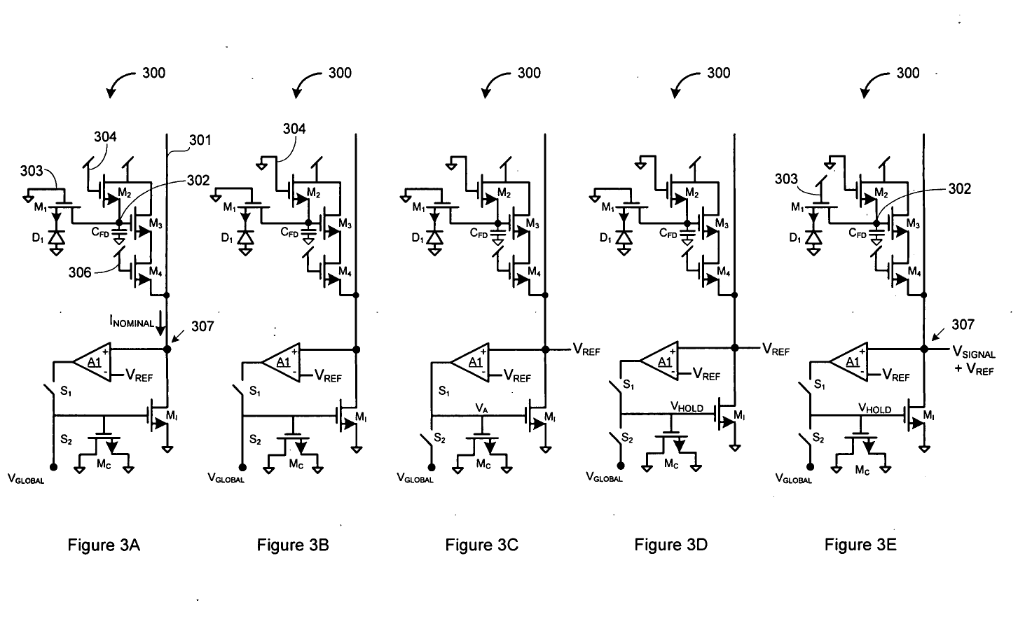

FIGS. 3A through 3E illustrate one embodiment of an output auto-zeroing circuit 300 in an active pixel. In FIGS. 3A through 3E, a four transistor (M₁, M₂, M₃, M₄) active pixel is coupled to an output circuit which includes an operational amplifier A₁, a current sink transistor M₁, a transistor MC configured as a capacitor, and switches S₁ and S₂. The inverting input of operational amplifier A1 is connected to a reference voltage VREF.

FIG. 3A illustrates an initial state of a four transistor active pixel in one embodiment. In FIG. 3A, a transfer gate transistor, M₁, is in an off state (gate 303 grounded), a reset transistor M₂ is in an on state (gate 304 connected to Vcc). Source follower M₃ is turned on by the source voltage of M₂ and connected to column line 301 through row select transistor M₄, which is on by virtue of its gate 306 being connected to Vcc. Switch S₁ is open and switch S₂ is closed, holding the gate of transistor MB at a voltage VGLOBAL, causing MB to sink a current INOMINAL. This sequence initializes the charge on floating diffusion capacitance CFD and sets the voltages of sense node 302 and output node 307 to initial values.

Next, as illustrated in FIG. 3B, reset gate M₂ is turned off by grounding its gate 304. Then, as shown in FIG. 3C, switch S₂ is opened and switch S₁ is closed (i.e., break before make). The closure of switch S₂ closes a feedback loop around operational amplifier A₁. The output voltage VA of operational amplifier A₁ drives the gate 308 of transistor MB. Transistor MB acts as a voltage to current converter to force the voltage of output node 307 to the reference voltage VREF. Voltage VA is stored in the capacitance of transistor MC, which together with switch S₁ forms a sample and hold circuit.

Next, as illustrated in FIG. 3D, switch S₁ is opened, fixing the voltage at gate 308 of MB at VHOLD=VA and the voltage at output node 307 at VREF. Diode D₁, having been exposed to light (e.g., by a camera shutter) at some time during or prior to the sequence from FIG. 3A through 3D, contains accumulated charge in its junction capacitance.

As illustrated in FIG. 3E, transfer gate M₁ is turned on by raising the voltage at its gate 303, allowing the accumulated charge in D₁ to transfer to sense node 302. M₁ is subsequently turned off once the charge transfer completes (not shown in FIG. 3E). The resulting voltage at sense node 302 (V=Q/C, where Q is the transferred charge and C is the floating diffusion capacitance CFD at sense node 302) is referred to output node 307 through source follower M₃ and row select transistor M₄ to generate a signal voltage VSIGNAL that is added to VREF. Because VREF is a known offset voltage that is uniform across all pixels, VSIGNAL can be recovered from each pixel output by simply subtracting the known value of VREF from the voltage at output node 307, without double sampling.

Embodiments of the present invention may also be used to enhance correlated double sampling (CDS) systems. For example, VREF may be selected to be substantially less than a highest expected value of offset voltage in a conventional CDS system, thereby reducing the required common-mode rejection ratio (CMRR) of differencing circuitry and/or reducing the headroom requirements of the differencing circuitry to increase dynamic range.

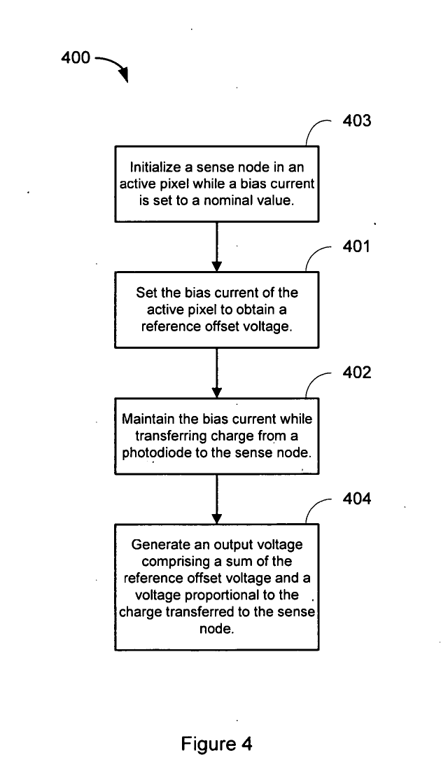

Thus, as illustrated in FIG. 4, a method 400 for output auto-zeroing an active pixel includes setting a bias current of an active pixel to obtain a reference offset voltage (operation 401), and maintaining the bias current while transferring charge from a photodiode in the active pixel to a sense node of the active pixel (operation 402). In one embodiment, the method also includes initializing the output node of the active pixel when the bias current is set to a nominal current value (operation 403), and generating an output voltage of the active pixel comprising a sum of the reference offset voltage and a voltage proportional to the charge transferred to the sense node (operation 404).

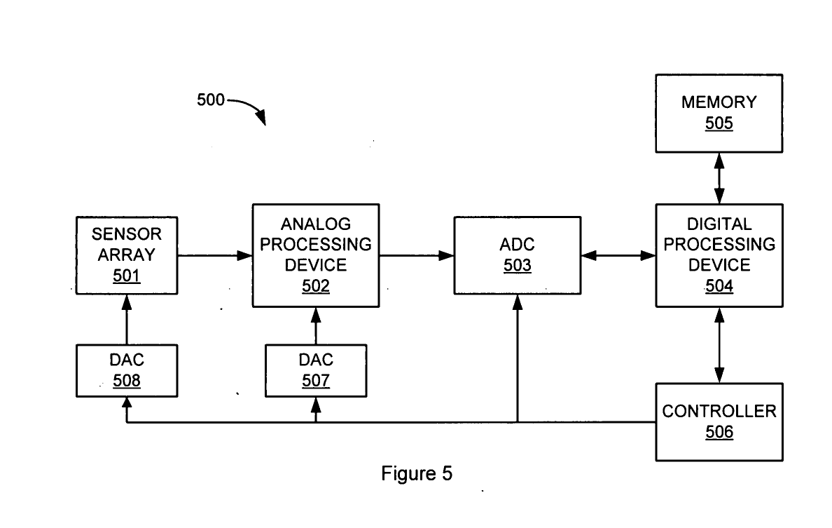

FIG. 5 illustrates a system 500 in which embodiments of the present invention may be implemented. In FIG. 5, a sensor array 501 containing an array of active pixels, such as an array of active pixels 300 described above, is coupled to an analog processing device 502. Analog processing device 502 may buffer, amplify and otherwise condition and/or manipulate outputs from sensor array 501, such as pixel outputs 307 described above. Analog processing device 502 may be coupled to an analog-to-digital converter (ADC) 503. Analog-to-digital converter 503 may be coupled to a digital processing device 504. Digital processing device 504 may be coupled to a memory 505 and a controller 506. Memory 505 may be any type of machine-readable storage medium as described above. Controller 506 may be coupled to ADC 503 and thereby control ADC 503. Controller 506 may also be coupled to sensor array 501 and analog processing device 502 through digital-to-analog converters (DACs) 508 and 507, respectively, to control sensor array 501 and analog processing device 502. Digital processing device 504 may be one or more general-purpose processing devices such as a microprocessor or central processing unit, or the like. Alternatively, digital processing device 504 may include one or more special-purpose processing devices such as a digital signal processor (DSP), an application specific integrated circuit (ASIC), a field programmable gate array (FPGA), or the like. Digital processing device 504 may also include any combination of a general-purpose processing device and a special-purpose processing device. Controller 505 may be configured to generate digital control signals to control ADC 503, and which may be converted to analog control signals by digital-to-analog converter (DAC) 507 and DAC 508 to control analog processing device 502 and image sensor 501, respectively. The analog control signals may include signals such as VTRANSFER, VRESET and VSELECT as described above. The analog control signals may also include signals to control switches S₁ and S₂ in the manner described above.

The image sensor 501 may be a CMOS integrated circuit fabricated on one or more common integrated circuit die that may be packaged in a common carrier. In one embodiment, one or more of digital processing device 504, memory 505 and controller 506 may be disposed on the integrated circuit die outside of an imaging area of the die. In one embodiment, some or all of the analog and digital components of system 500 may be integrated in one or more analog/digital mixed signal ASIC.

Embodiments of the present invention have been illustrated with a photodiode device type and CMOS technology using N-channel MOSFET devices for ease of discussion. In alternative embodiments, other device types (e.g., photogate and phototransistor), device technologies (e.g., charge coupled device (CCD) and buried channel CMOS), and process technologies (e.g., nMOS, buried channel CMOS and BiCMOS) may be used. Furthermore, the image sensors discussed herein may be applicable for use with all types of electromagnetic (EM) radiation (i.e., wavelength ranges) such as, for example, visible, infrared, ultraviolet, gamma, x-ray, microwave, etc. In one particular embodiment, the image sensors and pixel structures discussed herein are used with EM radiation in approximately the 300-1100 nanometer (nm) wavelength range (i.e., visible light to near infrared spectrum). Alternatively, the image sensors and pixel structures discussed herein may be used with EM radiation in other wavelength ranges.

Embodiments of the invention have been described with respect to CMOS active pixel sensors using photosensitive devices. However, the present invention is applicable to any image sensor that resets a capacitor in a sensing scheme including, for example, a fingerprint sensor based on capacitive sensing.

Embodiments of the present invention have been illustrated with reference to “rows” and “columns” of an image sensor array for ease of discussion. It will be appreciated that rows and columns in an array do not necessarily denote any particular direction or orientation of the array.

The image sensor and pixel structures discussed herein may be used in various applications including, but not limited to, a digital camera system, for example, for general-purpose photography (e.g., camera phone, still camera, video camera) or special-purpose photography (e.g., in automotive systems, hyper-spectral imaging in space borne systems, etc). Alternatively, the image sensor and pixel structures discussed herein may be used in other types of applications, for example, machine and robotic vision, document scanning, microscopy, security, biometry, etc.

What is claimed is:

1. A method, comprising:
dynamically biasing an active pixel with a bias current to obtain a reference offset voltage; and
maintaining the bias current while transferring charge from a photodiode in the active pixel to a sense node of the active pixel.

2. The method of claim 1, further comprising:
initializing the sense node of the active pixel when the bias current is set to a nominal current value; and
generating an output voltage of the active pixel comprising a sum of the reference offset voltage and a voltage proportional to the charge transferred to the sense node.

3. The method of claim 1, wherein dynamically biasing the active pixel comprises comparing an offset voltage of the active pixel with a reference voltage and adjusting a control voltage of a voltage-to-current converter to drive the offset voltage to the reference voltage.

4. The method of claim 3, wherein maintaining the bias current comprises storing the control voltage of the voltage-to-current converter, and transferring the charge comprises charging a capacitance of the sense node.

5. An apparatus, comprising:
one or more active pixels comprising a plurality of active pixels; and
an amplifier, coupled with the plurality of active pixels, to dynamically bias an offset voltage of a selected active pixel to a reference voltage.

6. The apparatus of claim 5, wherein each active pixel in the plurality of active pixels comprises a photodiode to convert light to charge, and four transistors comprising:
a reset gate, coupled to a sense node, to initialize a voltage at the sense node;
a transfer gate coupled between the photodiode and the sense node to transfer the charge from the photodiode to the sense node, wherein the sense node is configured to develop a sense voltage;
a source follower coupled to the sense node to add the sense voltage to the offset voltage; and
a row select gate to connect the amplifier with the selected active pixel.

7. The apparatus of claim 5, wherein the amplifier comprises:
an operational amplifier coupled with the plurality of active pixels, the operational amplifier configured to compare the offset voltage to the reference voltage;
a sample and hold element coupled to one of an output of the operational amplifier and a global reference voltage; and
a current source coupled between the sample and hold element and the plurality of active pixels, the current source to convert a sample and hold voltage to a bias current required to dynamically bias the offset voltage to the reference voltage.

8. The apparatus of claim 7, further comprising a switch to connect the sample and hold element to the output of the operational amplifier or to the global reference voltage or to neither the output of the operational amplifier or the global reference voltage.

9. The apparatus of claim 6, wherein the sense node comprises a floating diffusion capacitance.

10. An article of manufacture, comprising:
a machine-accessible medium including data that, when accessed by a machine, cause the machine to perform operations comprising,
dynamically biasing an active pixel with a bias current to obtain a reference offset voltage; and
maintaining the bias current while transferring charge from a photodiode in the active pixel to a sense node of the active pixel.

11. The article of manufacture of claim 10, wherein the machine-accessible medium further includes data that cause the machine to perform operations comprising:
initializing the sense node of the active pixel when the bias current is set to a nominal current value; and
generating an output voltage of the active pixel comprising a sum of the reference offset voltage and a voltage proportional to the charge transferred to the sense node.

12. The article of manufacture of claim 10, wherein dynamically biasing the active pixel comprises:
comparing an offset voltage of the active pixel with a reference voltage; and
adjusting a control voltage of a voltage-to-current converter to drive the offset voltage to the reference voltage.

13. The article of manufacture of claim 12, wherein:
maintaining the bias current comprises storing the control voltage of the voltage-to-current converter; and
transferring the charge comprises charging a capacitance of the sense node.

14. A system, comprising:
a sensor array comprising a plurality of active pixels in a plurality of rows and a plurality of columns and a plurality of amplifiers coupled to the plurality of columns of active pixels; and
a processing device to control the sensor array, wherein the processing device is configured to
select a row of active pixels;
dynamically bias each active pixel in the row of active pixels with a bias current to obtain a uniform reference offset voltage across the row of active pixels; and
maintain the bias current in each active pixel while transferring charge from a photodiode in each active pixel to a sense node in each active pixel.

15. The system of claim 14, wherein the processing device is further configured to:
initialize the sense node in each active pixel in the row of active pixels when the bias current in each active pixel is set to a uniform value across the row of active pixels; and
generate an output voltage from each active pixel comprising a sum of the uniform reference offset voltage and a voltage proportional to the charge transferred to the sense node of each active pixel.

16. The system of claim 15, wherein the processing device is further configured to average the output voltages from two or more active pixels in the row of active pixels.

17. An apparatus, comprising:
means for dynamically biasing an active pixel with a bias current to obtain a reference offset voltage; and
means for maintaining the bias current while transferring charge from a photodiode in the active pixel to a sense node of the active pixel.

18. The apparatus of claim 17, further comprising:
means for initializing the sense node of the active pixel when the bias current is set to a nominal current value; and
means for generating an output voltage of the active pixel, the output voltage comprising a sum of the reference offset voltage and a voltage proportional to the charge transferred to the sense node.

19. The apparatus of claim 17, wherein the means for dynamically biasing the active pixel comprises means for comparing an offset voltage of the active pixel with a reference voltage and means for adjusting a control voltage of a voltage-to-current converter to drive the offset voltage to the reference voltage.

20. The apparatus of claim 19, wherein the means for maintaining the bias current comprises means for storing the control voltage of the voltage-to-current converter, and transferring the charge comprises charging a capacitance of the sense node.
